(19) United States
(12) Patent Application Publication
(10) Pub. No.: US 2015/0364295 A1
(43) Pub. Date: Dec. 17, 2015

(54) Identification of Trace Constituent Phases in Nuclear Power Plant Deposits Using Electron Backscatter Diffraction (EBSD)

(71) Applicant: AREVA Inc., Lynchburg, VA (US)

(72) Inventors: Beverly H. Cyrus, Appomattox, VA (US); Norvell W. White, JR., Goode, VA (US)

(21) Appl. No.: 14/739,623

(22) Filed: Jun. 15, 2015

Related U.S. Application Data
(60) Provisional application No. 62/011,928, filed on Jun. 13, 2014.

(51) Int. Cl. H01J 37/26; H01J 37/20; H01J 37/22; H01J 37/28

(52) U.S. Cl. CPC H01J 37/261; H01J 37/28; H01J 37/20; H01J 37/22; H01J 2237/2007; H01J 2237/2602

(57) ABSTRACT

The instant invention provides a method of identifying lead-bearing crystalline phases or compounds in deposits formed on surfaces, such as the heated surfaces of nuclear power plant systems. A deposit sample or specimen is obtained and examined to obtain an image, an area elemental composition spectrum, and an x-ray elemental map to identify a location containing a lead-bearing species of interest. Electron backscatter diffraction is then used to obtain a characteristic diffraction pattern from the location, which is compared to a library of known diffraction patterns to identify any lead-bearing crystalline phases or compounds present in the location. Finally, any potential phase or compound of the lead in the deposit sample is identified by comparing the elemental composition spectrum with the electron backscatter diffraction crystalline compound identification.

### CROSS-REFERENCE TO RELATED APPLICATIONS

This patent application claims the benefit of U.S. Provisional Patent Application No. 62/011,928 filed on Jun. 13, 2014, which is incorporated herein by reference in its entirety.

### BACKGROUND OF THE INVENTION

1. Field of the Invention

The present invention relates to an analytical process for deposits that form on the surfaces of nuclear power plant systems. More specifically, the present invention provides sample preparation and analysis methodology utilizing a combination of scanning electron microscopy (SEM), energy dispersive spectroscopy (EDS), and electron backscatter diffraction (EBSD) to determine the crystalline phases/compounds of trace constituents such as lead (Pb) in those deposits.

2. Description of the Related Art

Lead has been shown in many laboratory tests to accelerate stress corrosion cracking (SCC) in all nickel alloys used to date in pressurized water reactor (PWR) steam generator (SG) tubing. Lead is frequently observed in fluids and deposits throughout the PWR secondary systems—often at significantly higher levels than the soluble concentrations that have been demonstrated to accelerate SCC, and has been detected in tight stress corrosion cracks in Alloy 600 steam generator tubes. However, it has been difficult to establish clear correlations between laboratory results and plant operating experience, except in a small number of events involving severe lead contamination.

Identifying the chemical forms of lead that exist in steam generator tube and other deposits, as well as oxide films, could further the understanding of lead transport mechanisms and its role in accelerating SCC. It has been speculated that the incorporation of lead into complex phases with other species may lower its solubility and limit its ability to promote SCC. Analytical processes are needed to identify the phases/compounds of trace constituents such as lead in a variety of nuclear power plant system deposits. Bulk analysis techniques, such as conventional X-ray diffraction, lack the sensitivity required to detect species at trace level concentrations.

While elemental concentrations of lead have been measured extensively in deposit samples, characterization of its chemical form(s) has been very limited. Known prior work has focused primarily on deposits adhered to the surfaces of samples extracted from plant equipment or to the surfaces of metal coupons prepared for laboratory investigations. Analytical methods previously utilized have included X-ray photoelectron spectroscopy (XPS), grazing incidence X-ray diffraction, and nanobeam electron diffraction in conjunction with transmission electron microscopy (TEM). All surface analysis techniques have unique advantages and limitations, as well as sample preparation challenges. It is beneficial to develop additional analytical approaches to maximize the information obtained about the nature of deposits.

### SUMMARY OF THE INVENTION

The instant invention provides a method of identifying lead-bearing crystalline phases or compounds in deposits formed on surfaces, such as the heated surfaces of nuclear power plant systems. First, a deposit sample or specimen is obtained and secured in a metallurgical mount such that its surface can be ground and polished using standard metallographic grinding and polishing techniques. The sample can be obtained in the location in which it was formed, or the sample can be removed from the surface on which it was formed.

The sample is then examined, preferably using a high resolution scanning electron microscope (SEM), and various information about the sample is collected. Such information includes an image, an area elemental composition spectrum, and an x-ray elemental map to identify a location containing a lead-bearing species of interest. The image may be obtained utilizing secondary electron imaging or backscatter electron imaging, and the area elemental composition spectrum can be obtained utilizing energy dispersive spectroscopy.

Electron backscatter diffraction is then used to obtain a characteristic diffraction pattern from the location. A library of electron backscatter diffraction patterns for known substances is provided, and the electron backscatter diffraction pattern from the location is compared with those in the library to identify any lead-bearing crystalline phases or compounds present in the location. Finally, any potential phase or compound of the lead in the deposit sample is identified by comparing the elemental composition spectrum with the electron backscatter diffraction crystalline compound identification.

If needed to stabilize friable deposits, the method may further include vacuum impregnating the deposit sample with a low viscosity embedding medium, curing the embedding medium, and sectioning the embedding medium to extract the deposit sample and expose a surface on which it is formed to be examined.

### DESCRIPTION OF THE DRAWINGS

The present invention is described with reference to the accompanying drawings. It is intended that the embodiments and figures disclosed herein are to be considered illustrative rather than restrictive.

FIG. 1 shows a SEM image of a first location on a first sample.

FIG. 2 shows an EDS spectrum of the first location on the first sample.

FIG. 3 shows a diffraction pattern of the first location on the first sample.

FIG. 4 shows a diffraction pattern of the first location on the first sample.

FIG. 5 shows a SEM image of a second location on a first sample.

FIG. 6 shows an EDS spectrum of the second location on the first sample.

FIG. 7 shows a diffraction pattern of the second location on the first sample.

FIG. 8 shows a diffraction pattern of the second location on the first sample.

FIG. 9 shows a SEM image of a first location on a second sample.

FIG. 10 shows an EDS spectrum of the first location on the second sample.

FIG. 11 shows a diffraction pattern of the first location on the second sample.

FIG. 12 shows a diffraction pattern of the first location on the second sample.

FIG. 13 shows a SEM image of a second location on a second sample.

FIG. 14 shows an EDS spectrum of the second location on the second sample.

FIG. 15 shows a diffraction pattern of the second location on the second sample.

FIG. 16 shows a diffraction pattern of the second location on the second sample.

### DETAILED DESCRIPTION OF THE INVENTION

The instant invention provides a method of identifying lead-bearing crystalline phases or compounds in deposits formed on surfaces, such as the heated surfaces of nuclear power plant systems or any surface that is contacted by high temperature system fluids. This could include one or more of the following: heat exchanger tubes, supports, or shells; piping; fittings; fasteners; etc. Steam generator tubes are currently the predominant surface contemplated for use with the present invention. Using this method to characterize the chemical form(s) of lead in deposits from various locations in nuclear power plant systems provides additional insight into its role in crack initiation and/or growth. This information supports the mitigation and/or prevention of lead-assisted SCC in nuclear power plant systems, which will extend system/component life.

As a first step of the inventive method, a deposit sample or specimen is obtained. The sample can be obtained in the location in which it was formed, or the sample can be removed from the surface on which it was formed. A variety of methods and equipment can be used to collect deposit samples for analysis. The most commonly utilized method involves segregation of deposit specimens of interest from the material removed from steam generator tubesheets by high pressure water lancing. This material generally is formed of deposits that have settled onto the tubesheet from feedwater as it enters the generator, or deposits that have “spalled” or flaked off of tubes or other steam generator surfaces and fallen to the tubesheet. The lancing water is processed through a series of bag filters, and deposit samples are collected from these filters. In addition to high pressure lancing or flushing, alternate methods of obtaining deposit samples include scraping, deformation of components removed from service to flake off deposits, and various chemical cleaning process that are available for removing deposits from nuclear system components. Undissolved material can be filtered from these cleaning solutions.

If needed to stabilize friable deposits (that is, a sample that is easily crushed due to its thickness and/or porosity), the method may further include vacuum impregnating the deposit sample with a low viscosity embedding medium, curing the embedding medium, and sectioning the embedding medium to extract the deposit sample and to expose a surface on which it is formed so that the sample can be examined. A friable and/or porous sample will tend to crack or crumble during preparation for analysis. To mitigate this, the sample can be infiltrated and encapsulated using a low viscosity epoxy. To minimize voids and maximize penetration, the sample is placed in a vacuum chamber to remove air pockets and, while under vacuum, is immersed in and back-filled with epoxy. This process is often repeated a second time. While the sample is still in the uncured epoxy, the vacuum is replaced with several atmospheres of air pressure. This can assist in epoxy penetration.

The impregnating epoxies used are multi-part, chemically curing resins. Some require only time to cure (harden). The formulation typically used requires elevated temperatures to achieve a good cure. The sample may be placed in an oven (with or without being placed under pressure) to raise the temperature to the point that curing will occur.

After the epoxy has been impregnated with samples and the epoxy has cured, the result is a coin-like disk of epoxy with embedded sample(s). Samples are cut from the disk using a suitable saw, typically a small, precision diamond saw. The samples are cut to generate a usable-sized piece with a flat base so that the sample can stand (on its edge) with a section of the sample exposed at the base.

Once obtained and, if appropriate, stabilized, the sample is secured in a metallurgical mount. This may include properly orienting the cut sample and placing the oriented sample in a mold cup. The mold cup (typically 1.25″ diameter) is then filled with an epoxy resin and cured. A number of individual samples from a disk may be placed in the mount. After the metallurgical mount has cured, it is removed from the mold cup and the (bottom) face containing the impregnated sample(s) is ground flat and polished to a very fine finish (mirror-like). A finely polished sample surface is required for the analytical equipment (scanning electron microscope (SEM), energy dispersive spectroscopy (EDS), electron backscatter diffraction (EBSD), etc.) to produce useful results.

The sample is then examined, preferably using a high resolution scanning electron microscope, and various information about the sample is collected. Such information includes an image, an area elemental composition spectrum, and an x-ray elemental map to identify a location containing a lead-bearing species of interest. The image may be obtained utilizing secondary electron imaging or backscatter electron imaging, and the area elemental composition spectrum can be obtained utilizing energy dispersive spectroscopy. The high resolution microscope produces a rastered electron beam (probe) that is scanned over the area of interest of a sample to yield information about the sample. Several different signals generated by the scanned sample are generated, each containing specific information (e.g. secondary electrons, backscattered electrons, x-rays). The secondary electron (SE) signal produces an image somewhat similar to a light microscope, showing the topography/morphology of a sample. While the backscattered electron signal will show some topography, it is primarily used to image variations in composition over the surface of a sample. It is sometimes called compositional imaging. Areas within the scanned location will appear brighter if of higher average atomic number and darker if of lower atomic number.

Energy dispersive spectroscopy is typically referred to as EDS or EDX. The x-ray energies emitted from a sample being scanned by the electron beam depend on the material composition excited by the electron probe. These x-rays are captured by a special detector. They are called “characteristic x-rays” because each element present will produce a set of x-ray energies (a spectrum) unique to that element. An “area elemental composition spectrum” is a histogram of characteristic x-rays collected over a scanned area. The x-axis is calibrated to the x-ray energies of interest, and the y-axis is the total number of x-ray events collected. The result is a graphic (or digital file) of x-ray energy vs. emission intensity. This produces peaks (as seen on a graphic chart display) with each element present producing a specific family of peaks (energies).

Lead produces a unique family of x-ray energies. If lead is present in a scanned (or stationary point) area, the unique family of x-ray energies detected by EDS will allow it to be identified. However, EDS can only identify the elements in an analysis area, not the phase/compound. For example, using EDS an area may indicate the presence of oxygen, sulfur, iron, and lead. There is no way to tell how the elements are compounded. An additional technique, electron backscattered diffraction (EBSD), can provide a refined analysis and identify this as a mix of iron oxide and lead sulfide crystals.

Electron backscatter diffraction is then used to obtain a characteristic diffraction pattern from the location. Electron backscatter diffraction is a scanning electron microscope based microstructural-crystallographic technique to measure the crystallographic orientation. In electron backscatter diffraction, a stationary electron beam strikes a tilted crystalline sample and the diffracted electrons form a pattern on a fluorescent screen. This pattern is characteristic of the crystal structure and orientation of the sample region from which it was generated. It provides the absolute crystal orientation with sub-micron resolution.

This technique (EBSD) uses a highly polished sample as an electron diffraction grating. Patterns are generated by the diffraction of the incident electron beam and collected on a very special video camera. A characteristic diffraction pattern (also called a “Kikuchi pattern”) is the pattern of electrons diffracted by a crystalline sample. The pattern is unique to the composition of a crystal and the orientation of the crystal in a material. A library of electron backscatter diffraction patterns for known substances is provided, and the electron backscatter diffraction pattern from the location is compared with those in the library to identify any lead-bearing crystalline phases or compounds present in the location. A preferred library is the Inorganic Crystal Structure Database (ICSD), which contains a collection of pattern data collected world-wide by researchers over many years. The comparison is performed by examining the line angles and intercepts of the pattern to find a fit, and preferably is computer-implemented. The analytical software uses the elemental composition from EDS to search candidate compound patterns in the library. Finally, any potential phase or compound of the lead in the deposit sample is identified by comparing the elemental composition spectrum with the electron backscatter diffraction crystalline compound identification.

Using this method to characterize the chemical form(s) of lead in deposits from various locations in nuclear power plant systems provides additional insight into its role in crack initiation and/or growth. This information supports the mitigation and/or prevention of lead-assisted SCC in nuclear power plant systems, which will extend system/component life.

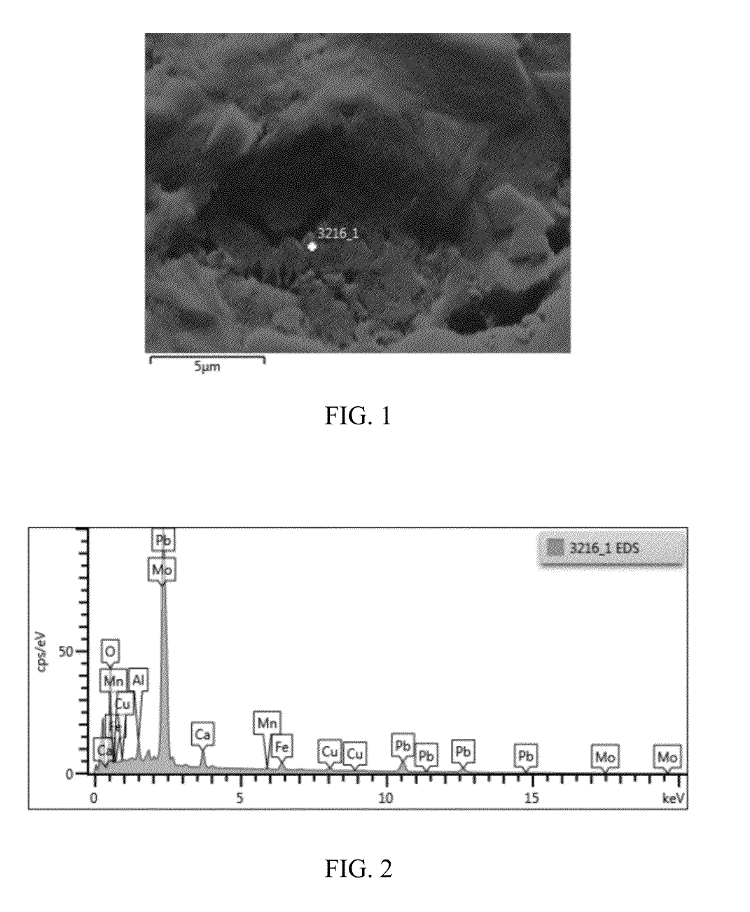

FIGS. 1-16 show results from two steam generator hard collar samples that were known to contain lead. The samples were encapsulated in an epoxy metallographic mounting material, ground, and polished to expose the deposit cross-section for analysis. X-ray mapping and EDS point analyses were used to locate lead-containing areas, as well as other materials, for the EBSD analyses.

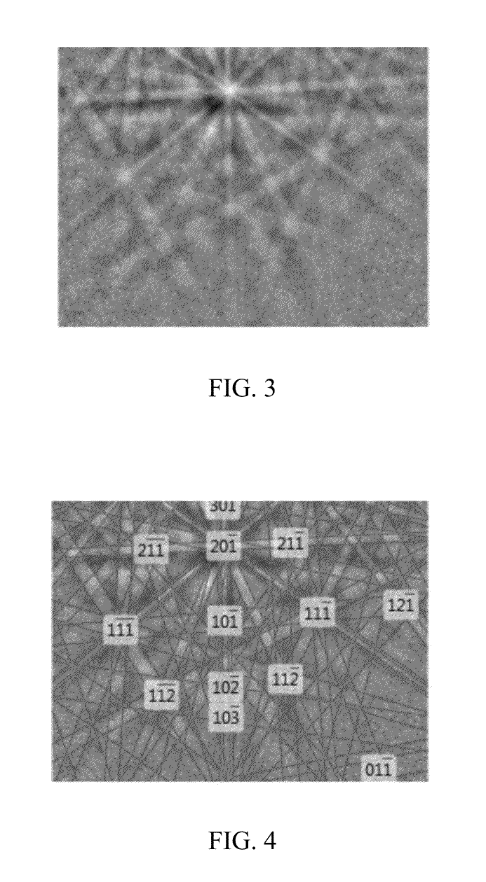

FIG. 1 shows an SEM image of a first location on the first hard collar, and FIG. 2 shows an EDS spectrum of the same. FIGS. 3 and 4 show diffraction patterns for the first sample, first location. The raw pattern of FIG. 3 has been modified in FIG. 4 to highlight the crystalline structure. The resulting phase identification for the first sample, first location is provided in Table 1 below.

TABLE 1

| Name | Wulfenite |
|---|---|
| Database | Inorganic Crystal Structure Database |
| Structure | |
| Crystal System | Tetragonal |
| Laue Group | 4 |
| Space Group | 88 |
| Unit Cell | |
| a | 5.42 Å |
| b | 5.42 Å |
| c | 12.08 Å |
| Alpha | 90.00° |
| Beta | 90.00° |
| Gamma | 90.00° |

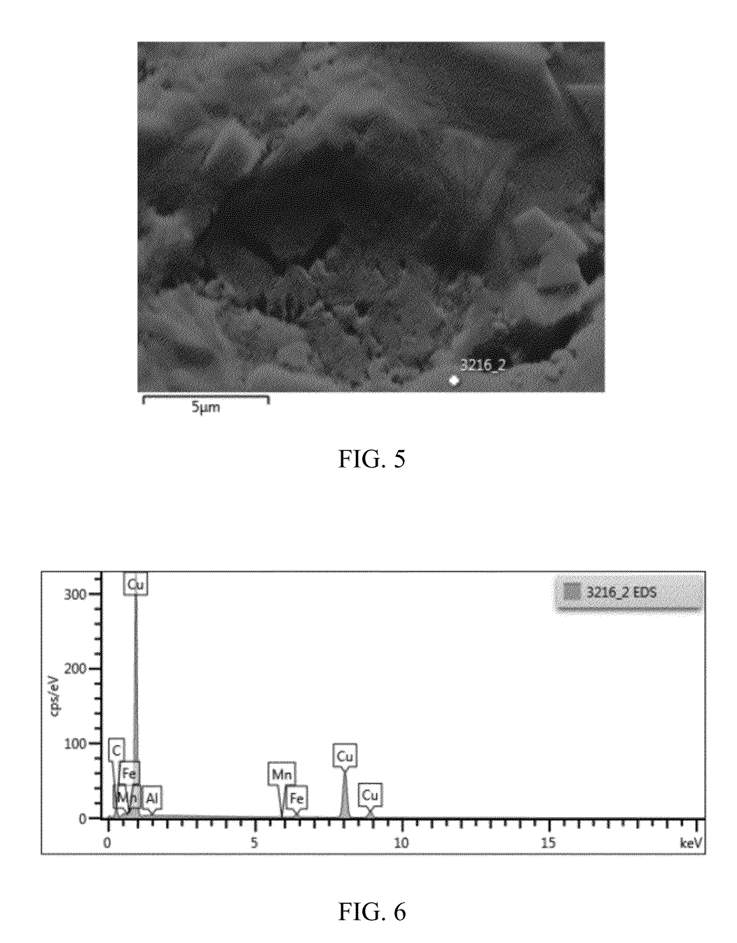

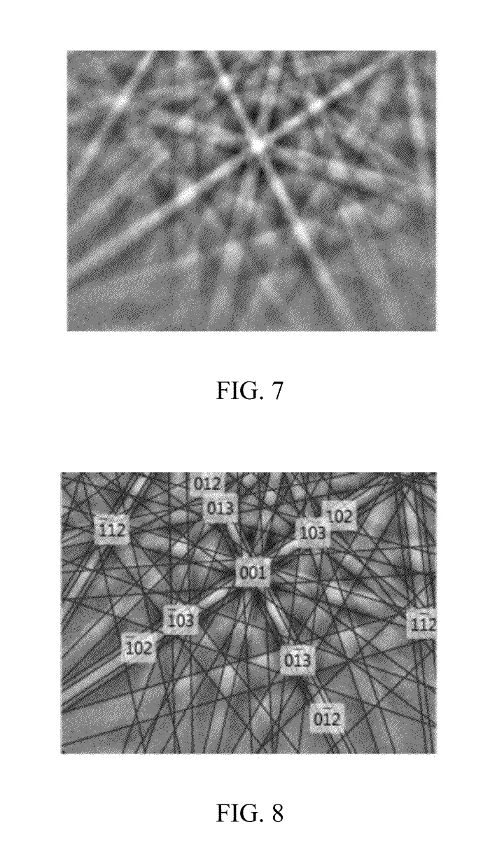

FIG. 5 shows an SEM image of a second location on the first hard collar, and FIG. 6 shows an EDS spectrum of the same. FIGS. 7 and 8 show diffraction patterns for the first sample, second location. The raw pattern of FIG. 7 has been modified in FIG. 8 to highlight the crystalline structure. The resulting phase identification for the first sample, second location is provided in Table 2 below.

TABLE 2

| Name | Copper |
|---|---|
| Database | Inorganic Crystal Structure Database |
| Structure | |
| Crystal System | Cubic |
| Laue Group | 11 |
| Space Group | 225 |
| Unit Cell | |
| a | 3.61 Å |
| b | 3.61 Å |
| c | 3.61 Å |
| Alpha | 90.00° |
| Beta | 90.00° |
| Gamma | 90.00° |

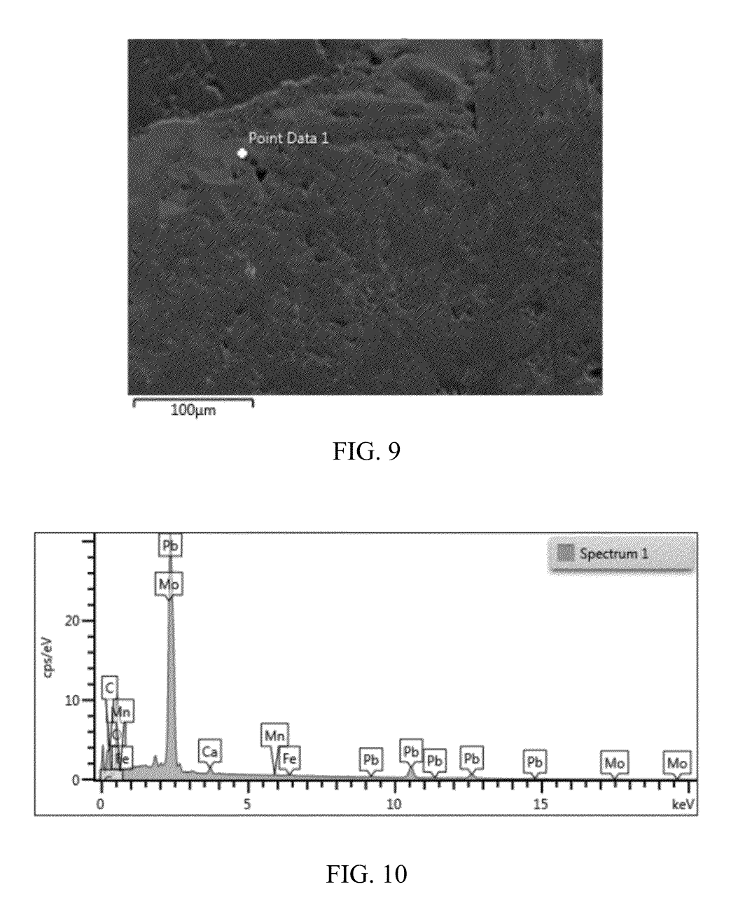

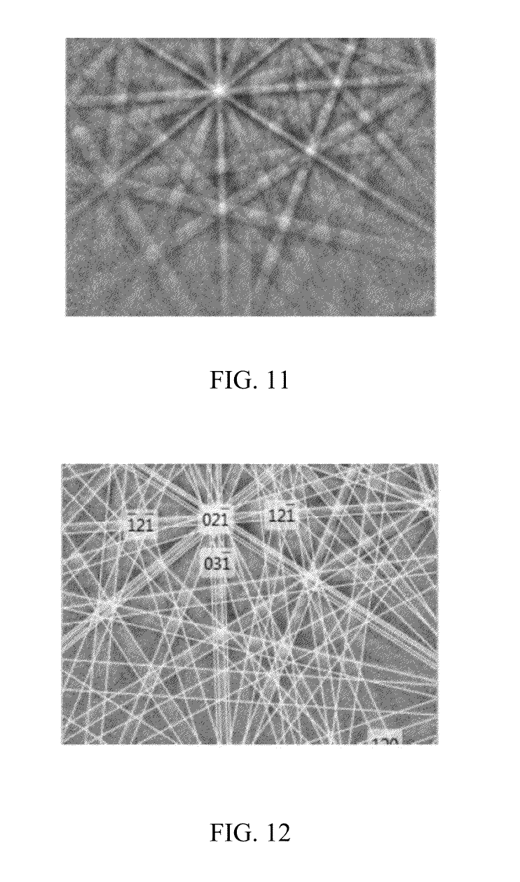

FIG. 9 shows an SEM image of a first location on the second hard collar, and FIG. 10 shows an EDS spectrum of the same. FIGS. 11 and 12 show diffraction patterns for the second sample, first location. The raw pattern of FIG. 11 has been modified in FIG. 12 to highlight the crystalline structure. The resulting phase identification for the second sample, first location is provided in Table 3 below.

TABLE 3

| Name | Wulfenite |
|---|---|
| Database | Inorganic Crystal Structure Database |
| Structure | |
| Crystal System | Tetragonal |
| Laue Group | 4 |
| Space Group | 88 |
| Unit Cell | |
| a | 5.43 Å |
| b | 5.43 Å |
| c | 12.11 Å |
| Alpha | 90.00° |
| Beta | 90.00° |
| Gamma | 90.00° |

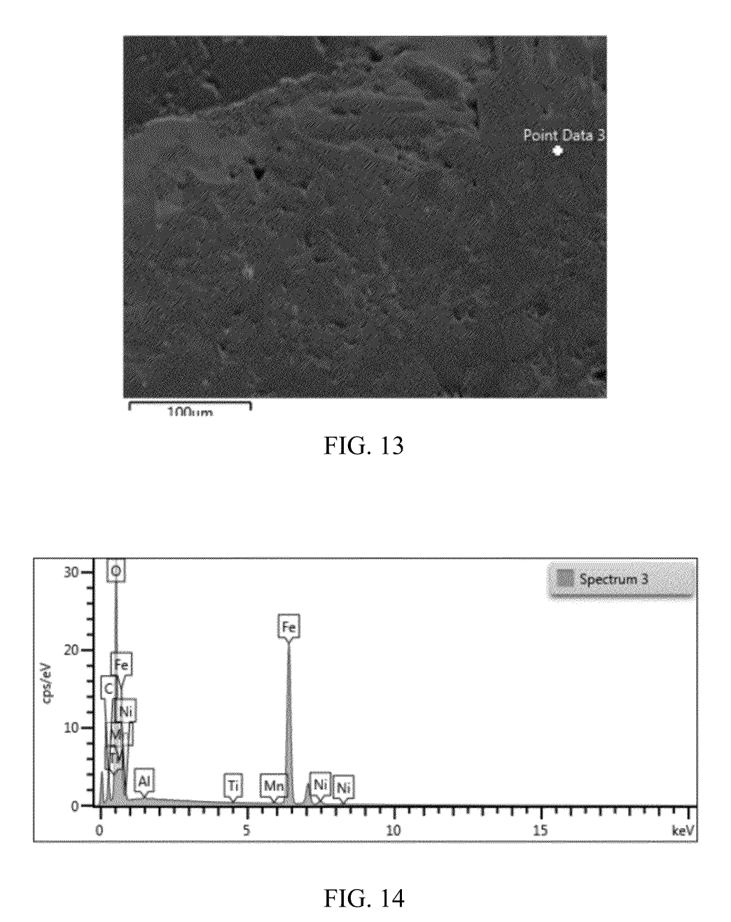

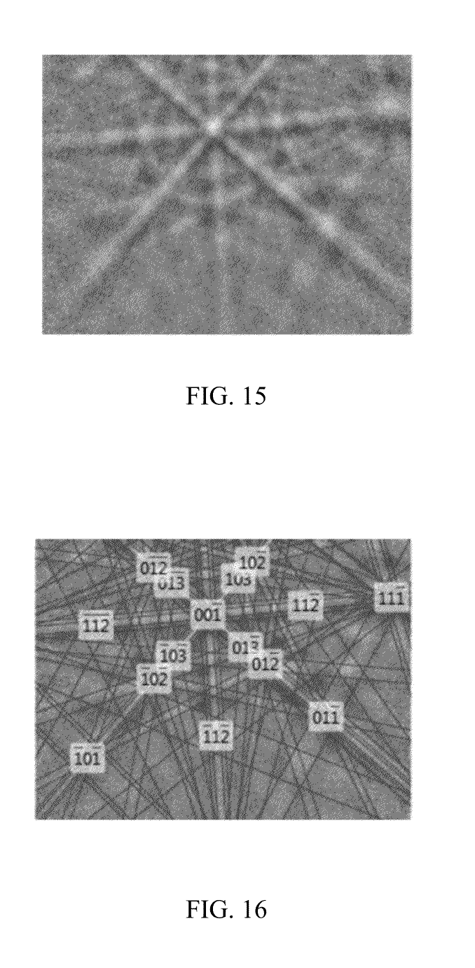

FIG. 13 shows an SEM image of a second location on the second hard collar, and FIG. 14 shows an EDS spectrum of the same. FIGS. 15 and 16 show diffraction patterns for the second sample, second location. The raw pattern of FIG. 15 has been modified in FIG. 16 to highlight the crystalline structure. The resulting phase identification for the second sample, second location is provided in Table 4 below.

TABLE 4

| Name | Magnetite low |
|---|---|
| Database | Inorganic Crystal Structure Database |
| Structure | |
| Crystal System | Orthorhombic |
| Laue Group | 3 |
| Space Group | 74 |
| Unit Cell | |
| a | 5.91 Å |
| b | 5.95 Å |
| c | 8.39 Å |
| Alpha | 90.00° |
| Beta | 90.00° |
| Gamma | 90.00° |

The phases identified in these two samples included magnetite, Fe₃O₄ (FIGS. 13-16), metallic copper, Cu (FIGS. 5-8), and the lead molybdate mineral wulfenite, PbMoO₄ (FIGS. 1-4 and 9-12). The molybdate was an unexpected result in light of earlier studies, but its presence is considered viable since both lead and molybdenum are frequently detected in steam generator deposits.

While the preferred embodiments of the present invention have been described above, it should be understood that they have been presented by way of example only, and not of limitation. It will be apparent to persons skilled in the relevant art that various changes in form and detail can be made therein without departing from the spirit and scope of the invention. Thus the present invention should not be limited by the above-described exemplary embodiments, but should be defined only in accordance with the following claims and their equivalents. Furthermore, while certain advantages of the invention have been described herein, it is to be understood that not necessarily all such advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other advantages as may be taught or suggested herein.

What is claimed is:

1. A method of identifying lead-bearing crystalline phases or compounds in deposits, comprising:
providing a library of electron backscatter diffraction patterns for known substances;
obtaining a deposit sample;
securing said deposit sample in a metallurgical mount, such that a surface of interest can be ground and polished;
examining said deposit sample;
obtaining information regarding said deposit sample including an image, an area elemental composition spectrum, and an x-ray elemental map to identify a location containing a lead-bearing species of interest;
utilizing electron backscatter diffraction to obtain a characteristic diffraction pattern from said location;
comparing said electron backscatter diffraction pattern from said location with said library patterns to identify any lead-bearing crystalline phases or compounds present in said location; and
identifying a potential phase or compound of the lead in said deposit sample by comparing said elemental composition spectrum with said electron backscatter diffraction crystalline compound identification.

2. The method of claim 1, wherein said obtaining a deposit sample includes obtaining said deposit sample adhered to a surface on which it was formed.

3. The method of claim 1, wherein said obtaining a deposit sample includes removing said deposit sample from a surface on which it was formed.

4. The method of claim 1, further comprising:
vacuum impregnating said deposit sample with a low viscosity embedding medium;
curing said embedding medium; and
sectioning said embedding medium to extract said deposit sample and expose a surface on which it is formed to be examined.

5. The method of claim 1, wherein said examining includes examining said deposit sample using a high resolution scanning electron microscope.

6. The method of claim 1, wherein said obtaining information includes obtaining said image utilizing secondary electron imaging or backscatter electron imaging.

7. The method of claim 1, wherein said obtaining information includes obtaining said area elemental composition spectrum utilizing energy dispersive spectroscopy.

8. The method of claim 1, wherein the deposit is an irradiated deposit and said obtaining a deposit sample includes obtaining said deposit sample from a nuclear power plant.
